(19) United States
(12) Patent Application Publication
(10) Pub. No.: US 2008/0024172 A1
(43) Pub. Date: Jan. 31, 2008

(54) Actively Compensated Buffering for High Speed Current Mode Logic Data Path

(75) Inventors: Quan Yu, Shanghai (CN); Ming Qu, San Jose, CA (US)

Correspondence Address: Thomas C. Chuang, Floor 3, 473 Jackson St., San Francisco, CA, 94111, US

(73) Assignee: Parade Technologies, Ltd.

(21) Appl. No.: 11/460,122

(22) Filed: Jul. 26, 2006

(51) Int. Cl. H03K 19/094

(52) U.S. Cl. 326/115

(57) ABSTRACT

An actively compensated CML circuit includes a CML buffer circuit and a bandwidth expansion circuit. The CML buffer circuit includes a first MOS transistor and a second MOS transistor in a differential pair configuration. A first load resistor is coupled to a first MOS transistor drain at a first output terminal and a second load resistor is coupled to a second MOS transistor drain at a second output terminal. The bandwidth expansion circuit is coupled to the CML buffer circuit in a source follower configuration. The bandwidth expansion circuit includes a third MOS transistor and a fourth MOS transistor. A capacitor is coupled across a third MOS transistor source and a fourth MOS transistor source. The fourth MOS transistor and the third MOS transistor generate a high pass function at the first output terminal and the second output terminal.

### BACKGROUND OF THE INVENTION

As data transfer requirements increase for both on-chip and inter-chip applications, transfer speed remains one of the most critical issues in modern integrated circuit design. Users desire high data transfer speed, but also simultaneously want reduced costs. This speed-cost requirement pushes high speed integrated circuit design to the limits of semiconductor processing. Current mode logic (CML) is widely used in modern high speed data path designs for its superior speed performance. However, CML still encounters speed limitations in multi-giga-bits per second applications.

In the prior art, there have been several techniques used to expand circuit bandwidth. One technique utilizes inductor shunt-peaking. A typical circuit using this technique is illustrated in FIG. 1 and discussed in “The Design of CMOS Radio-Frequency Integrated Circuits”, T. H. Lee, Cambridge University Press, 1998, pp. 146. Referring to FIG. 1, the circuit enhances the CML buffer bandwidth for high speed applications by using inductors L1 and L2 to peak the high frequency response. However, the implementation of inductors in modern semiconductor manufacturing process requires significant die area which is proportional to the chip cost.

FIG. 2 shows an alternative prior art approach using an active compensation technique. This technique is discussed in “Inductor-less, 10 Gb/s Limiter with 10 mV sensitivity and Offset/Temperature Compensation in Baseline CMOS18”, M.A.T. Sanduleanu and E. Stikvvort, Proceeding of the 29^{th} European Solid-State Circuit Conference, pp. 153-156, September 2003. The input signals IN+ and IN− are linearly amplified by transistor M1 and transistor M6, and also are linearly replicated at the drains of transistor M2 and transistor M5, and consequently they are followed at the sources of transistor M7 and transistor M8. The current flowing through capacitor C is proportional to the derivative of voltage across it. Since the voltage across C is a linear copy of the input differential voltage, the current through C is proportional to the derivative of the input signal. This current is injected into output loading resistor R1. Since the derivative is in fact a high pass signal processing function, the approach illustrated in FIG. 2 can boost the output slew rate by adding more high frequency components at the output nodes OUT+ and OUT−. However, with the circuit shown in FIG. 2, the generation of the copy of the input signal cannot be completed without delay as the transistors M2 and M5 load the input stage. Additionally, the power consumed by transistor M2, transistor M5 and resistor R2 can be significant.

Thus, there is a need for improved systems and methods for high speed current mode logic circuits.

### BRIEF DESCRIPTION OF THE DRAWINGS

The present invention will be readily understood by the following detailed description in conjunction with the accompanying drawings, wherein like reference numerals designate like structural elements.

FIG. 1 illustrates a prior art circuit for increasing circuit bandwidth using inductor shunt peaking.

FIG. 2 illustrates a further prior art circuit for increasing circuit bandwidth.

FIG. 3 illustrates a circuit for increasing circuit bandwidth in a high speed current mode logic data path system in an example of the invention.

FIG. 4 illustrates a circuit for increasing circuit bandwidth in a high speed current mode logic data path system in a further example of the invention.

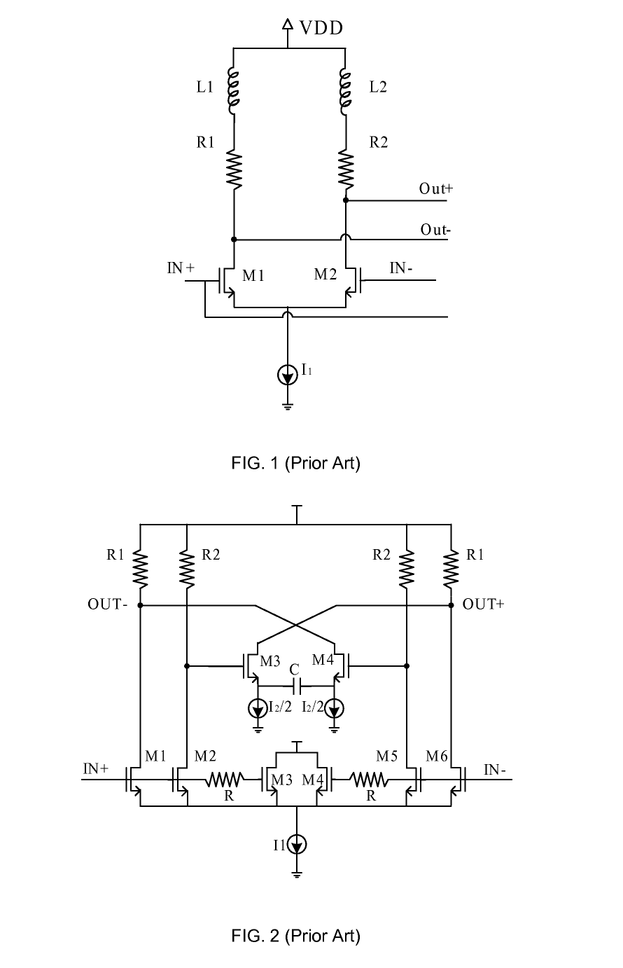

### DESCRIPTION OF SPECIFIC EMBODIMENTS

Systems and methods for actively compensated buffering for high speed current mode logic data paths are disclosed. The following description is presented to enable any person skilled in the art to make and use the invention. Descriptions of specific embodiments and applications are provided only as examples and various modifications will be readily apparent to those skilled in the art. The general principles defined herein may be applied to other embodiments and applications without departing from the spirit and scope of the invention. Thus, the present invention is to be accorded the widest scope encompassing numerous alternatives, modifications and equivalents consistent with the principles and features disclosed herein. For purpose of clarity, details relating to technical material that is known in the technical fields related to the invention have not been described in detail so as not to unnecessarily obscure the present invention.

Particular circuit layouts and circuit components may be given for illustrative purposes. This is done for illustrative purposes to facilitate understanding only and one of ordinary skill in the art may vary the design and implementation parameters and still remain within the scope of the invention.

Generally this description relates to the design and manufacture of integrated semiconductor circuits. In particular, circuits that provide actively compensated buffering for high speed current mode logic data paths are discussed. The systems and methods described herein can be applied to any high speed current mode logic (CML) design to expand bandwidth and boost edge slew rate. Typical applications include, but are not limited to, PCI Express, HDMI/DVI, DisplayPort, Serial ATA, SONET, Rapid IO, and XAUI.

In one example, the circuits and methods boost the signal edge slew rate in order to expand the data path frequency bandwidth, thereby increasing data transfer speed. Active components in the form of additional transistors are added to a CML buffer circuit to boost high frequency gain and thereby increase the overall frequency bandwidth. The system is advantageously used to provide a simple and efficient solution to expand bandwidth and boost signal edge slew rates in high speed CML data paths. The system provides an effective solution for very high speed CML design using a cost efficient approach with limited design effort.

In one example of the invention, a current mode logic circuit includes a first MOS transistor and a second MOS transistor. The first MOS transistor has a first MOS transistor gate, a first MOS transistor source, and a first MOS transistor drain. The second MOS transistor has a second MOS transistor gate, a second MOS transistor source, and a second MOS transistor drain. A first data input terminal is coupled to the first MOS transistor gate and a second data input terminal is coupled to the second MOS transistor gate. A first current source is coupled to the first MOS transistor source and the second MOS transistor source. A first load resistor coupled to the first MOS transistor drain and a second load resistor is coupled to the second MOS transistor drain.

The circuit further includes a third MOS transistor and a fourth MOS transistor. The third MOS transistor has a third MOS transistor gate, a third MOS transistor source, and a third MOS transistor drain. The third MOS transistor gate is coupled to the second MOS transistor gate. The fourth MOS transistor has a fourth MOS transistor gate, a fourth MOS transistor source, and a fourth MOS transistor drain. The fourth MOS transistor gate is coupled to the first MOS transistor gate. A capacitor is coupled between the third MOS transistor source and the fourth MOS transistor source. A first output terminal is coupled to the first MOS transistor drain and the fourth MOS transistor drain. A second output terminal is coupled to the second MOS transistor drain and the third MOS transistor drain.

In one example of the invention, an actively compensated CML circuit includes a CML buffer circuit and a bandwidth expansion circuit. The CML buffer circuit includes a first MOS transistor and a second MOS transistor in a differential pair configuration. A first load resistor is coupled to a first MOS transistor drain at a first output terminal and a second load resistor is coupled to a second MOS transistor drain at a second output terminal. The bandwidth expansion circuit is coupled to the CML buffer circuit in a source follower configuration. The bandwidth expansion circuit includes a third MOS transistor and a fourth MOS transistor. A third MOS transistor gate is coupled to a second MOS transistor gate, a fourth MOS transistor gate is coupled to a first MOS transistor gate, a third MOS transistor drain is coupled to the second output terminal, and a fourth MOS transistor drain is coupled to the first output terminal. A capacitor is coupled across a third MOS transistor source and a fourth MOS transistor source. The fourth MOS transistor and the third MOS transistor generate a high pass function at the first output terminal and the second output terminal.

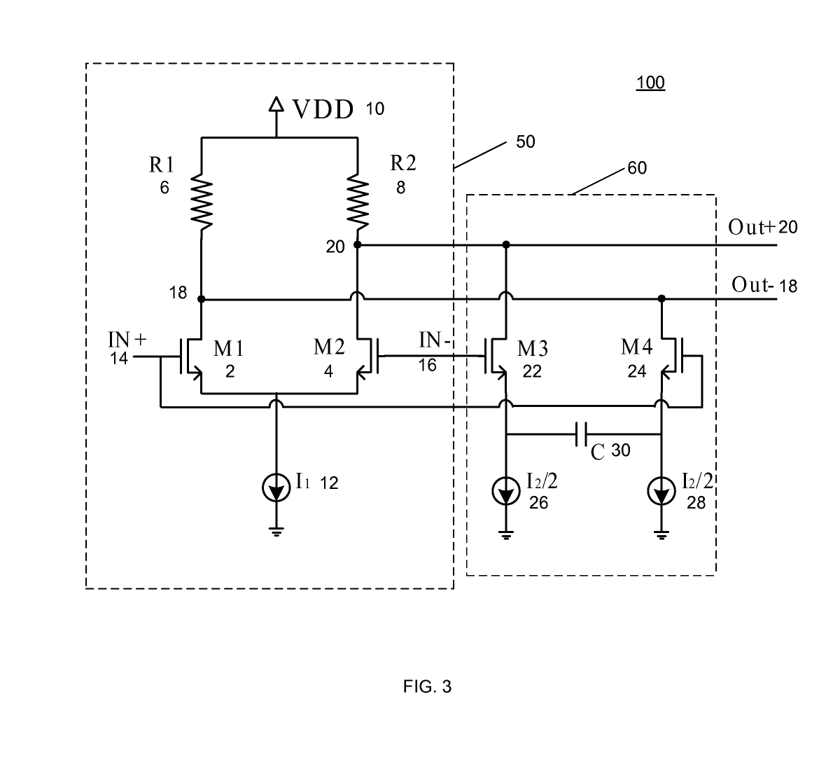

Referring to FIG. 3, the inventive circuit 100 includes a traditional CML buffer circuit 50 (also referred to herein as the “main stage”) consisting of a differential pair of transistors NMOS transistor M12, NMOS transistor M2 4, load resistors R1 6, R2 8, and a current source I1 12 that feeds the sources of the differential transistor pair.

The CML buffer circuit 50 utilizes NMOS transistors M12 and M2 4 as a differential logic pair. The gate electrode of NMOS transistor M12 is connected to input line IN+ 14, the source electrode is connected to constant-current source I1 12, and the drain electrode is connected to output line Out-18 and load element R1 6. The gate electrode of NMOS transistor M2 4 is connected to input line IN− 16, the source electrode is connected to constant current source 11 12, and the drain electrode is connected to output line Out+ 20 and load element R2 8.

The operation of the CML buffer circuit 50 will next be explained with reference to FIG. 3. If for example, an input signal and its reverse signal are inputted to current-mode logic buffer circuit 50 from input lines IN+ 14 and line IN− 16, respectively, and the input signal of input line IN+ 14 changes from high level to low level, NMOS transistor M1 2 switches from a conductive state to a nonconductive state and NMOS transistor M2 4 switches from a nonconductive state to a conductive state. The path of the constant current switches and a voltage drop occurs at load element R2 8 without a voltage drop occurring at load element R1 6. The signal at output line Out− 18 changes to high level and the signal at output line Out+ 20 changes to low level.

Referring again to FIG. 3, the inventive circuit 100 includes a bandwidth expansion circuit 60 (also referred to herein as the “boosting stage”) consisting of a NMOS transistor M3 22, NMOS transistor M4 24, current source ½ I2 26, current source ½ I2 28, and capacitor C 30. The gate electrode of NMOS transistor M3 22 is connected to input line IN− 16, the source electrode is connected to current source ½ I2 26, and the drain electrode is coupled to output line Out+ 20. The gate electrode of NMOS transistor M4 24 is connected to input line IN+ 14, the source electrode is connected to current source ½ I2 28, and the drain electrode is coupled to output line Out− 18. Capacitor C 30 is coupled across the source electrodes of NMOS transistor M3 22 and NMOS transistor M4 24.

In operation, circuit 100 provides a simple and efficient solution for an actively compensated CML buffer. The differential pair of NMOS transistor M12 and NMOS transistor M2 4 is the main amplifier stage, and the pair of transistors NMOS transistor M3 22 and NMOS transistor M4 24 is in a source follower configuration. The input signal at input line IN+ 14 and input line IN− 16 is directly fed to the gates of NMOS transistor M3 22 and NMOS transistor M4 24. As a result of the source follower configuration, a signal copy is replicated at the sources of NMOS transistor M3 22 and NMOS transistor M4 24. The current flowing through the capacitor C 30 is proportional to the derivative of the voltage across the capacitor. Since the voltage across capacitor C 30 is the replica of the input signal, the current through capacitor C 30 is the derivative of the input signal with a scaling coefficient.

The current summations at load resistor R1 6 resulting from NMOS transistor M1 2 and NMOS transistor M4 24, and at load resistor R2 8 from NMOS transistor M2 4 and NMOS transistor M3 22 generate a high pass function, resulting in a gain boost at high frequencies and thereby expanding the frequency bandwidth. In particular, the current resulting from NMOS transistor M3 22 and NMOS transistor M4 24 generate a high pass function.

The currents flowing through R1 and R2 result in a differential voltage V(Out+, Out−) at Out+ 20 and Out− 18:

V(Out+,Out−)=A0*V(IN+,IN−)+A1*d/dt[V(IN+,IN−)]

where V(IN+,IN−) and V(Out+,Out−) are the differential voltages at input and out respectively, A0 and A1 are constant gain coefficients, and d/dt denotes derivative operation. The second component of V(Out+,Out−), A1*d/dt[V(IN+,IN−)], results from the addition of bandwidth expansion circuit 60 and corresponds to an increased edge slew rate. As described below, the increased edge slew rate corresponds to an increased overall frequency bandwidth of circuit 100 relative to CML buffer circuit 50 alone.

The above formula for V(Out+,Out−) is a time domain description of the relationship between input signal and output signal. It can also be presented in frequency domain as

Vo(s)/Vi(s)=A0+A1*s

where Vi(s) and Vo(s) are the Laplace transforms of the input and output signals, and s is the Laplace operator. It is known that this transfer function presents a high pass function. The high pass function operates to expand the overall frequency bandwidth of circuit 100.

Compared to the prior art circuit illustrated in FIG. 2, the circuit 100 minimizes the skew of the two branch currents since there is no additive delay from M1 and M2 to M3 and M4. The delay difference between main stage and boosting stage can be minimized too, which in turn moves the secondary parasitic poles formed by the delay difference to a much higher frequency. Reduced skew and reduced delay difference impact achieve maximum boosting characteristics without introducing significant distortion at the output. The invented solution saves power by removing two extra current branches. Since no extra head room is required, this architecture is suitable for low voltage applications.

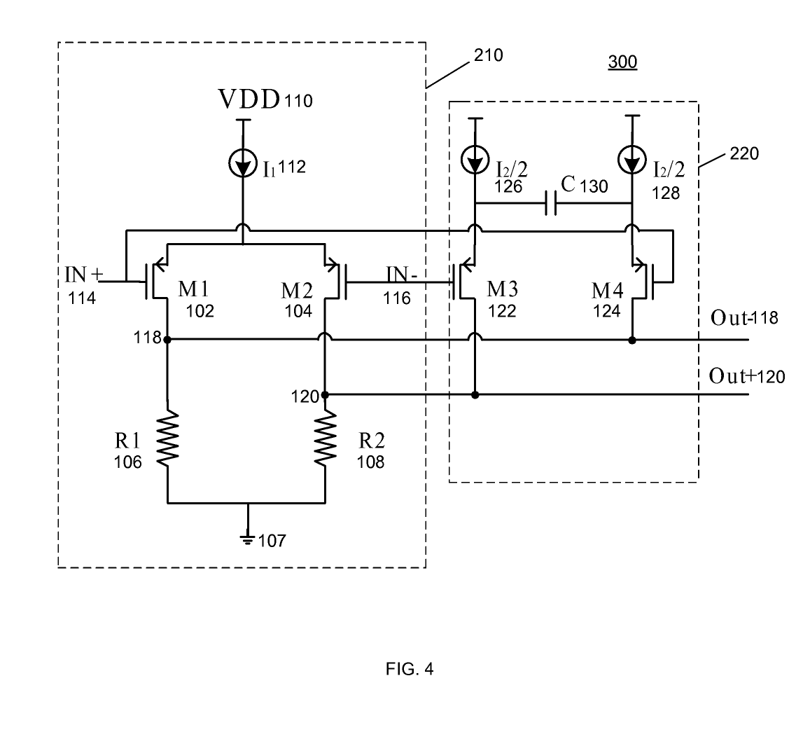

FIG. 3 illustrates a supply referenced CML buffer. Referring to FIG. 4, in a further example of the invention a ground referenced CML buffer circuit is illustrated. Referring to FIG. 4, the ground-referenced circuit 300 includes a traditional CML logic buffer circuit 210 consisting of a differential pair of transistors PMOS transistor M1 102, PMOS transistor M2 104, load resistors R1 106, R2 108, and a current source I1 112 that feeds the sources of the differential transistor pair.

The ground-referenced CML buffer circuit 300 is a buffer circuit taking PMOS transistors M1 102 and M2 104 as a differential logic pair. The gate electrode of PMOS transistor M1 102 is connected to input line IN+ 114, the source electrode is connected to constant-current source 11 112, and the drain electrode is connected to output line Out− 118 and load element R1 106. Load element R1 106 is also coupled to a ground 107. The gate electrode of PMOS transistor M2 104 is connected to input line IN− 116, the source electrode is connected to constant current source I1 112, and the drain electrode is connected to output line Out+ 120 and load element R2 108. Load element R2 108 is also coupled to ground 107. Constant current source I1 112 is coupled to a supply voltage Vdd 110.

Referring again to FIG. 4, the ground-referenced CML buffer circuit 300 includes a bandwidth expansion circuit 220 consisting of a PMOS transistor M3 122, PMOS transistor M4 124, current source ½ I2 126, current source ½ I2 128, and capacitor C 130. The gate electrode of PMOS transistor M3 122 is connected to input line IN− 116, the source electrode is connected to current source ½ I2 126, and the drain electrode is coupled to output line Out+ 120. The gate electrode of PMOS transistor M4 124 is connected to input line IN+ 114, the source electrode is connected to current source ½ 128, and the drain electrode is coupled to output line Out− 118. Capacitor C 130 is coupled across the source electrodes of PMOS transistor M3 122 and PMOS transistor M4 124. In operation, the ground-referenced circuit 300 operates in a manner similar to the circuit 100 as described above in reference to FIG. 3.

Although example circuit configurations have been described in certain example of the invention, one of ordinary skill in the art will recognize that except as otherwise described herein other configurations and components may be used to perform similar functions. While the exemplary embodiments of the present invention are described and illustrated herein, it will be appreciated that they are merely illustrative and that modifications can be made to these embodiments without departing from the spirit and scope of the invention. Thus, the scope of the invention is intended to be defined only in terms of the following claims as may be amended, with each claim being expressly incorporated into this Description of Specific Embodiments as an embodiment of the invention.

What is claimed is:

1. A current mode logic circuit comprising:
a first MOS transistor having a first MOS transistor gate, a first MOS transistor source, and a first MOS transistor drain;
a second MOS transistor having a second MOS transistor gate, a second MOS transistor source, and a second MOS transistor drain;
a first data input terminal coupled to the first MOS transistor gate;
a second data input terminal coupled to the second MOS transistor gate;
a first current source coupled to the first MOS transistor source and the second MOS transistor source;
a first load resistor coupled to the first MOS transistor drain;
a second load resistor coupled to the second MOS transistor drain;
a third MOS transistor having a third MOS transistor gate, a third MOS transistor source, and a third MOS transistor drain, wherein the third MOS transistor gate is coupled to the second MOS transistor gate;
a fourth MOS transistor having a fourth MOS transistor gate, a fourth MOS transistor source, and a fourth MOS transistor drain, wherein the fourth MOS transistor gate is coupled to the first MOS transistor gate;
a capacitor coupled between the third MOS transistor source and the fourth MOS transistor source;
a first output terminal coupled to the first MOS transistor drain and the fourth MOS transistor drain; and
a second output terminal coupled to the second MOS transistor drain and the third MOS transistor drain.

2. The current mode logic circuit of claim 1, wherein the first MOS transistor drain and the second MOS transistor drain are coupled to a power source voltage via the first load resistor and the second load resistor.

3. The current mode logic circuit of claim 1, wherein the first MOS transistor, second MOS transistor, third MOS transistor, and fourth MOS transistor comprise NMOS transistors.

4. The current mode logic circuit of claim 1, wherein the first MOS transistor, second MOS transistor, third MOS transistor, and fourth MOS transistor comprise PMOS transistors.

5. The current mode logic circuit of claim 1, wherein the first MOS transistor and the second MOS transistor are utilized as a differential logic pair.

6. The current mode logic circuit of claim 1, further comprising a second current source coupled to the third MOS transistor source and a third current source coupled to the fourth MOS transistor source.

7. An actively compensated CML circuit comprising:
a CML buffer circuit comprising a first MOS transistor and a second MOS transistor in a differential pair configuration, wherein a first load resistor is coupled to a first MOS transistor drain at a first output terminal and a second load resistor is coupled to a second MOS transistor drain at a second output terminal;
a bandwidth expansion circuit coupled to the CML buffer circuit in a source follower configuration, comprising:
a third MOS transistor;
a fourth MOS transistor, wherein a third MOS transistor gate is coupled to a second MOS transistor gate, a fourth MOS transistor gate is coupled to a first MOS transistor gate, a third MOS transistor drain is coupled to the second output terminal, and a fourth MOS transistor drain is coupled to the first output terminal; and
a capacitor coupled across a third MOS transistor source and a fourth MOS transistor source,
wherein the fourth MOS transistor and the third MOS transistor generate a high pass function at the first output terminal and the second output terminal.

8. The actively compensated CML circuit of claim 7, wherein the first MOS transistor drain and the second MOS transistor drain are coupled to a power source voltage via the first load resistor and the second load resistor.

9. The actively compensated CML circuit of claim 7, wherein the first MOS transistor, second MOS transistor, third MOS transistor, and fourth MOS transistor comprise NMOS transistors.

10. The actively compensated CML circuit of claim 7, wherein the first MOS transistor, second MOS transistor, third MOS transistor, and fourth MOS transistor comprise PMOS transistors.

11. The actively compensated CML circuit of claim 7, further comprising a first current source coupled to a first MOS transistor source and a second MOS transistor source

12. The actively compensated CML circuit of claim 11, further comprising a second current source coupled to the third MOS transistor source and a third current source coupled to the fourth MOS transistor source.
